(19) United States
(12) Patent Application Publication
(10) Pub. No.: US 2025/0130664 A1
(43) Pub. Date: Apr. 24, 2025

(54) DISPLAY MODULE, DISPLAY APPARATUS, DRIVING METHOD FOR DISPLAY MODULE, AND PIXEL CIRCUIT

(71) Applicants: Hefei Visionox Technology Co., Ltd., Hefei (CN); KunShan Go-Visionox Opto Electronics Co., Ltd, Kunshan (CN)

(72) Inventors: Qiangqiang SONG, Hefei (CN); Yunjie LIU, Hefei (CN); Bo RAO, Hefei (CN); Yuan YAO, Hefei (CN); Tiegang WANG, Hefei (CN)

(73) Assignees: Hefei Visionox Technology Co., Ltd., Hefei (CN); KunShan Go-Visionox Opto Electronics Co., Ltd, Kunshan (CN)

(21) Appl. No.: 18/675,510

(22) Filed: May 28, 2024

(30) Foreign Application Priority Data
Oct. 23, 2023 (CN) 202311385943.6

(51) Int. Cl. G06F 3/041; G06F 3/044; H10K 59/121; H10K 59/122; H10K 59/131; H10K 59/40

(52) U.S. Cl. CPC G06F 3/04164; G06F 3/0446; H10K 59/1213; H10K 59/122; H10K 59/131; H10K 59/40

(57) ABSTRACT

A display module, a display apparatus, a driving method for a display module, and a pixel circuit. The display module includes: an array base plate; a light-emitting unit arranged at a side of the array base plate and including a first electrode, a second electrode, and a light-emitting portion; a pixel definition layer arranged at a side of the array base plate, the pixel definition layer including a pixel definition portion and a pixel opening defined by the pixel definition portion, and at least a portion of the first electrode being exposed from the pixel opening, in which one of the first electrode and the second electrode is configured to receive a touch driving signal, and the other one of the first electrode and the second electrode is configured to output a touch sensing signal.

### CROSS REFERENCE TO RELATED APPLICATION

The present application claims priority to Chinese Patent Application No. 202311385943.6 filed on Oct. 23, 2023, which is incorporated herein by reference in its entirety.

### TECHNICAL FIELD

The present application relates to the field of display technology, and particularly to a display module, a display apparatus, a driving method for a display module, and a pixel circuit.

### BACKGROUND

Planar display apparatus based on Organic Light Emitting Diode (OLED) and Light Emitting Diode (LED), etc., are widely used in cell phones, TVs, notebook computers, desktop computers and other consumer electronic products due to their high image quality, power saving, thin body and wide range of applications, and have become the mainstream of the display apparatus.

However, the performance of current OLED display products needs to be improved.

### SUMMARY

Embodiments of the present application provide a display module, a display apparatus, a driving method for a display module, and a pixel circuit, aiming to improve the performance of the display module.

Some embodiments of a first aspect of the present application provide a display module, including: an array base plate; a light-emitting unit arranged at a side of the array base plate and including a first electrode located in a first electrode layer, a second electrode located in a second electrode layer, and a light-emitting portion located in a light-emitting functional layer, the second electrode being located at a side of the first electrode away from the array base plate, and the light-emitting portion being located between the second electrode and the first electrode; a pixel definition layer arranged at a side of the array base plate, the pixel definition layer including a pixel definition portion and a pixel opening defined by the pixel definition portion, and at least a portion of the first electrode being exposed from the pixel opening, in which one of the first electrode and the second electrode is configured to receive a touch driving signal, and the other one of the first electrode and the second electrode is configured to output a touch sensing signal.

Some embodiments of a second aspect of the present application provide a display apparatus including the display module according to any of the above implementation.

Some embodiments of a third aspect of the present application provide a driving method for the display module according to any of the above implementation, each light-emitting unit has a display cycle including at least one light emitting stage and at least one non-light emitting stage, and the driving method includes: transmitting a driving current signal to the first electrode of the light-emitting unit in the light emitting stage of the light-emitting unit; and transmitting the touch driving signal or the reset signal to the first electrode of the light-emitting unit in the non-light emitting stage of the light-emitting unit.

Some embodiments of a fourth aspect of the present application provide a pixel circuit, including: a light-emitting unit; a light emitting control transistor connected with the light-emitting unit; and a touch driving transistor connected with the light-emitting unit, in which in a light emitting stage, the touch driving transistor is turned off, and the light emitting control transistor is turned on to control the light-emitting unit to emit light; in a non-light emitting stage, the light emitting control transistor is turned off, and the touch driving transistor is turned on and transmits a touch driving signal to the light-emitting unit.

The display module according to the embodiments of the present application includes the array base plate, the light-emitting unit, and the pixel definition layer. The pixel definition layer includes the pixel definition portion and the pixel opening defined by the pixel definition portion, at least a portion of the light-emitting unit may be located in the pixel opening, and the pixel definition portion can be used to divide sub-pixels of the display module.

The light-emitting unit includes the first electrode located in the first electrode layer, the second electrode located in the second electrode layer, and the light-emitting portion located in the light-emitting functional layer, the second electrode is located at a side the first electrode away from the base plate, the light-emitting portion is located between the second electrode and the first electrode, and the first electrode, the light-emitting portion, and the second electrode that are stacked can be used to cause the display module to emit light and display.

One of the first electrode and the second electrode is configured to receive the touch driving signal, the other one of the first electrode and the second electrode is configured to output the touch sensing signal, so that the first electrode and the second electrode not only can be used as a pixel electrode of the display module for participating in light emitting and display of the display module, but also can be reused as a touch electrode of the display module for achieving touch control function for the display module, and thus no additional layer structure is required for the display module to arrange the touch electrode, the performance of the display module is improved, and for example, the display module can have a less thickness.

### BRIEF DESCRIPTION OF THE DRAWINGS

In order to more clearly illustrate the technical solutions of the embodiments of the present application, the drawings to be used in the embodiments of the present application will be briefly introduced below. It is obvious that the drawings described below are merely some embodiments of the present application, and for those of ordinary skill in the art, other drawings can be obtained based on these drawings without inventive effort.

FIG. 1 shows a partial schematic structural diagram of a pixel definition layer according to an embodiment of the present application;

FIG. 2 shows a partial sectional view of a display module according to an embodiment of the present application;

FIG. 3 shows a partial schematic structural diagram of a display module according to an embodiment of the present application;

FIG. 4 shows a partial schematic structural diagram of a display module according to another embodiment of the present application;

FIG. 5 shows a partial schematic structural diagram of a display module according to yet another embodiment of the present application;

FIG. 6 shows a partial sectional view of a display module according to another embodiment of the present application;

FIG. 7 shows a partial schematic structural diagram of a display module according to yet another embodiment of the present application;

FIG. 8 shows a partial sectional view of a display module according to yet another embodiment of the present application;

FIG. 9 shows a partial sectional view of a display module according to yet another embodiment of the present application;

FIG. 10 shows a partial sectional view of a display module according to yet another embodiment of the present application;

FIG. 11 shows a partial sectional view of a display module according to yet another embodiment of the present application;

FIG. 12 shows a schematic flow chart of a driving method for a display module according to an embodiment of the present application;

FIG. 13 shows a schematic sequence chart of a driving method for a display module according to an embodiment of the present application;

FIG. 14 shows a schematic sequence chart of a driving method for a display module according to another embodiment of the present application;

FIG. 15 shows a schematic structural diagram of a pixel circuit according to an embodiment of the present application;

FIG. 16 shows a schematic structural diagram of a pixel circuit according to another embodiment of the present application;

FIG. 17 shows a schematic structural diagram of a pixel circuit according to another embodiment of the present application.

### REFERENCE NUMERALS

10, display module; 10a, touch control module; 10b, touch control line;
100, array base plate; 110, substrate; 120, first insulation layer; 130, second insulation layer; 140, third insulation layer; 150, fourth insulation layer; 160, source-drain conductive portion;
200, first electrode layer; 210, first electrode; 211, first portion; 212, second portion;
310, isolation structure; 310a, first end portion; 310b, second end portion; 311, first isolation portion; 312, second isolation portion; 320, pixel definition layer; 321, pixel definition portion; 321a, accommodating slot; 322, pixel opening;
400, light-emitting functional layer; 410, light-emitting portion;
500, second electrode layer; 510, second electrode;
610, touch driving transistor; 611, first gate; 612, first source; 613, first drain; 614, first active layer; 620, touch driving signal line;
700, touch sensing signal line;
800, light emitting control transistor; 810, second gate; 820, second source; 830, second drain; 840, second active layer;
900, driving transistor;
VDD, power supply voltage signal line;
EM, light emitting control signal line;
EL, light-emitting unit;
VDATA, data signal end;
VREF, initialization signal end;
S1, first scanning signal end;
S2, second scanning signal end;
T1, first control transistor; T2, second control transistor;
P1, storage module; C1, first capacitor;
P2, data writing module; T3, data writing transistor;
P3, compensation module; T4, compensation transistor; T4a, first sub-transistor; T4b, second sub-transistor;
P4, initialization module; T5, initialization transistor; T5a, third sub-transistor; T5b, fourth sub-transistor;
X, thickness direction;
Y, first direction;
Z, second direction.

### DETAILED DESCRIPTION

Features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely configured to explain the present application, rather than to limit the present application. For those skilled in the art, the present application can be implemented without some of these specific details. The following description of the embodiments is merely to provide a better understanding of the present application by illustrating the examples of the present application.

It should be noted that, in the present application, the relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device comprising/including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

It should be understood that when describing the structure of a component, if a layer/area is referred to as being “on” or “above” another layer/region, it may mean that the layer/area is directly on the other layer/region or that other layers/regions may be included between the layer/area and the other layer/area. Moreover, if the component is turned over, the layer/region will be “below” or “under” the other layer/region.

Planar display apparatus based on Organic Light Emitting Diode and Light Emitting Diode, etc., are widely used in cell phones, TVs, notebook computers, desktop computers and other consumer electronic products due to their high image quality, power saving, thin body and wide range of applications, and have become the mainstream of the display apparatus. However, the performance of current OLED display products needs to be improved.

In order to solve the above problems, the embodiments of the present application provide a display module, a display apparatus, a driving method for the display module, and a pixel circuit, and various embodiments of the display module, the display apparatus, the driving method for the display module, and the pixel circuit will be described below in connection with the accompanying drawings.

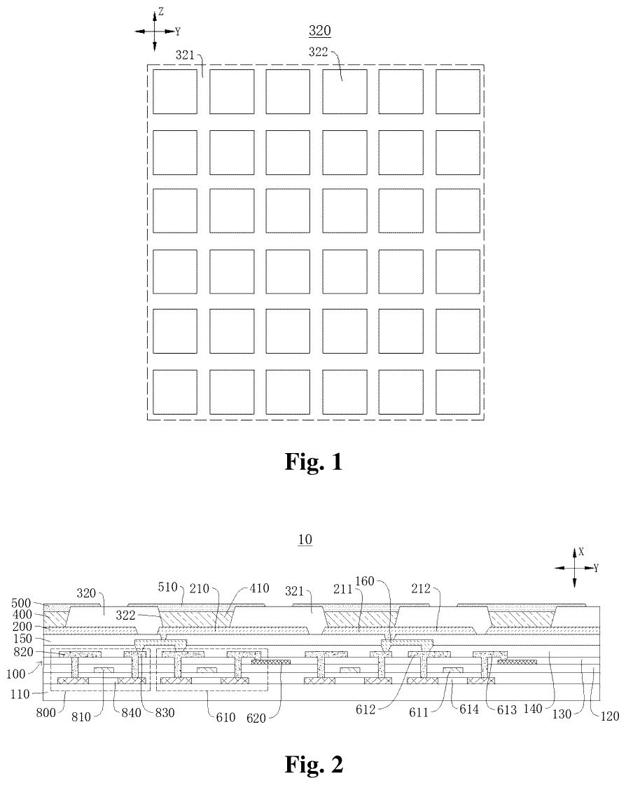

FIG. 1 shows a partial schematic structural diagram of a pixel definition layer 320 according to an embodiment of the present application, and FIG. 2 shows a partial sectional view of a display module 10 according to an embodiment of the present application. In the figures, direction X is a thickness direction of the display module 10, direction Y is a first direction, and direction Z is a second direction, in which the first direction Y, the second direction Z, and the thickness direction X are intersected with each other.

In order to show the structure of the display module 10 more clearly, the touch driving transistors 610 and the light emitting control transistors 800 connected with a portion of the first electrodes 210 are not illustrated in the relevant partial sectional views of the display module 10, i.e., only a portion of the touch driving transistors 610 and the light emitting control transistors 800 are illustrated, and thus the actual numbers and shapes of the touch driving transistors 610 and the light emitting control transistors 800 arranged in an actual product are not limited by the relevant accompanying drawings.

The embodiments of the present application provide a display module 10, which may be an Organic Light Emitting Diode (OLED) display module 10.

As shown in FIGS. 1 and 2, the embodiments of the first aspect of the present application provide a display module 10, including: an array base plate 100; a light-emitting unit EL arranged at a side of the array base plate 100 and including a first electrode 210 located in a first electrode layer 200, a second electrode 510 located in a second electrode layer 500, and a light-emitting portion 410 located in a light-emitting functional layer 400, the second electrode 510 being located at a side of the first electrode 210 away from the array base plate 100, and the light-emitting portion 410 being located between the second electrode 510 and the first electrode 210; and a pixel definition layer 320 arranged at a side of the array base plate 100, the pixel definition layer 320 including a pixel definition portion 321 and a pixel opening 322 defined by the pixel definition portion 321, and at least a portion of the first electrode 210 being exposed from the pixel opening 322, in which one of the first electrode 210 and the second electrode 510 is configured to receive a touch driving signal, and the other one of the first electrode 210 and the second electrode 510 is configured to output a touch sensing signal.

The display module 10 according to the embodiments of the present application includes the array base plate 100, the light-emitting unit EL, and the pixel definition layer 320. The pixel definition layer 320 includes the pixel definition portion 321 and the pixel opening 322 defined by the pixel definition portion 321, at least a portion of the light-emitting unit EL may be located in the pixel opening 322, and the pixel definition portion 321 can be used to divide sub-pixels of the display module 10.

The light-emitting unit EL includes the first electrode 210 located in the first electrode layer 200, the second electrode 510 located in the second electrode layer 500, and the light-emitting portion 410 located in the light-emitting functional layer 400, the second electrode 510 is located at a side the first electrode 210 away from the base plate 100, the light-emitting portion 410 is located between the second electrode 510 and the first electrode 210, and the first electrode 210, the light-emitting portion 410, and the second electrode 510 that are stacked can be used to cause the display module 10 to emit light and display.

One of the first electrode 210 and the second electrode 510 is configured to receive the touch driving signal, the other one of the first electrode 210 and the second electrode 510 is configured to output the touch sensing signal, so that the first electrode 210 and the second electrode 510 not only can be used as a pixel electrode of the display module 10 for participating in light emitting and display of the display module 10, but also can be reused as a touch electrode of the display module 10 for achieving touch control function for the display module 10, and thus no additional layer structure is required for the display module 10 to arrange the touch electrode, and the display module 10 can have a less thickness.

In some embodiments of the present application, the light-emitting portion 410 may include a Hole Inject Layer (HIL), a Hole Transport Layer (HTL), a light-emitting structure, an Electron Inject Layer (EIL), and an Electron Transport Layer (HTL).

Optionally, the display module 10 may include at least two first electrodes 210 and at least two second electrodes 510, the adjacent first electrodes 210 are spaced apart from each other, and the adjacent second electrodes 510 are spaced apart from each other, so as to achieve the touch control function for the display module 10.

The first electrode 210 and the second electrode 510 may be used as the pixel electrode of the display module 10 for participating in light emitting and display of the display module 10, in which one of the first electrode 210 and the second electrode 510 is used as an anode and the other is used as a cathode, so as to drive the light-emitting portion 410 to emit light. In the embodiments of the present application, for example, the first electrode 210 is the anode of the display module 10, and the second electrode 510 is the cathode of the display module 10.

As shown in FIG. 1, optionally, the pixel definition portion 321 may be a mesh in shape, and the hollow area in the mesh pixel definition portion 321 may form the pixel opening 322. Optionally, a portion of the pixel definition portion 321 may be formed extending along the first direction Y, and a portion of the pixel definition portion 321 may be formed extending along the second direction Z, so that the pixel definition portion 321 may be interleaved to form the mesh.

Herein, the size and arrangement shape of each pixel opening 322 may be set in various manners. Optionally, the size and arrangement shape of each pixel opening 322 may be set according to the color of the light emitted by the light-emitting portion 410 in the pixel opening 322. Alternatively, the size and arrangement shape of each pixel opening 322 may be set further according to the requirement for the pixel arrangement density of the display module 10.

In some embodiments of the present application, the display module 10 may be a display module in which touch positioning is implemented based on a mutual-capacitive touch architecture, i.e., under a condition that the first electrode 210 and the second electrode 510 are used as the touch electrode of the display module 10, one of the first electrode 210 and the second electrode 510 may be used as a touch driving electrode for excitation, the other one may be used as a touch sensing electrode for detection, and a capacitor can be formed between the first electrode 210 and the second electrode 510. Therefore, a user may press, touch or approach a certain position of the display module 10 to enable the capacitance between the first electrode 210 and the second electrode 510 at that position to be changed, so that the identification and positioning can be performed through the change of the capacitance, so as to achieve the touch control function for the display module 10.

As an example, the user may press a certain position of the display module 10 to reduce a distance between the first electrode 210 and the second electrode 510, so that the capacitance between the first electrode 210 and the second electrode 510 at that position is increased. As another example, the user may touch or approach, using a conductor, a certain position of the display module 10 to enable the conductor to affect the induced capacitance between the first electrode 210 and the second electrode 510, so that the induced capacitance between the first electrode 210 and the second electrode 510 at that position is reduced.

For ease of description, in the following embodiments, for example, the first electrode 210 is used as the touch driving electrode of the display module 10, and the second electrode 510 is used as the touch sensing electrode of the display module 10.

As shown in FIG. 2, in some optional embodiments, at least a portion of an orthographic projection of the first electrode 210 on the array base plate 100 is staggered with an orthographic projection of the second electrode 510 on the array base plate 100.

At least a portion of the orthographic projection of the first electrode 210 on the array base plate 100 is staggered with the orthographic projection of the second electrode 510 on the array base plate 100, so that at least a portion of the first electrode 210 is not blocked and covered by the second electrode 510 in the thickness direction X of the display module 10, and thus an induced capacitor can be formed in the overlapped area between the first electrode 210 and the second electrode 510 under a condition that the first electrode 210 and the second electrode 510 are used as the touch electrode. Therefore, when the conductor approaches the first electrode 210 and the second electrode 510, the induced capacitance between the first electrode 210 and the second electrode 510 can be changed. For example, the induced capacitance between the first electrode 210 and the second electrode 510 is reduced when the user's finger approaches the first electrode 210 and the second electrode 510.

In some embodiments of the present application, at least a portion of the orthographic projection of the first electrode 210 on the array base plate 100 may be staggered with the orthographic projection of the second electrode 510 on the array base plate 100 in various manners.

As shown in FIG. 2, in some optional embodiments, each first electrode 210 includes a first portion 211 exposed from the pixel opening 322 and a second portion 212 located between the pixel definition portion 321 and the array base plate 100, and at least a portion of an orthographic projection of the second portion 212 on the array base plate 100 is staggered with the orthographic projection of the second electrode 510 on the array base plate 100.

Optionally, the second portion 212 is located at at least one side of the first portion 211 in the first direction Y or the second direction Z.

In these optional embodiments, at least a portion of the orthographic projection of the second portion 212 on the array base plate 100 is staggered with the orthographic projection of the second electrode 510 on the array base plate 100, so that the first electrode 210 can have a greater arrangement area, facilitating that the orthographic projection of the first electrode 210 on the array base plate 100 is staggered with the orthographic projection of the second electrode 510 on the array base plate 100. Therefore, the second portion 212 can be configured to form an induced capacitor with the second electrode 510, and further the first portion 211 under the light-emitting portion 410 can be configured to participate in light emitting and display of the display module 10.

Moreover, the second portion 212 located under the pixel definition portion 321 can be further configured to elevate the pixel definition portion 321, so as to enhance the dividing effect of the pixel definition portion 321 on the sub-pixels of the display module 10. Therefore, the pixel definition portion 321 does not require an excessively great height, but can still better divide the sub-pixels of the display module 10, so that the display module 10 can have a less thickness.

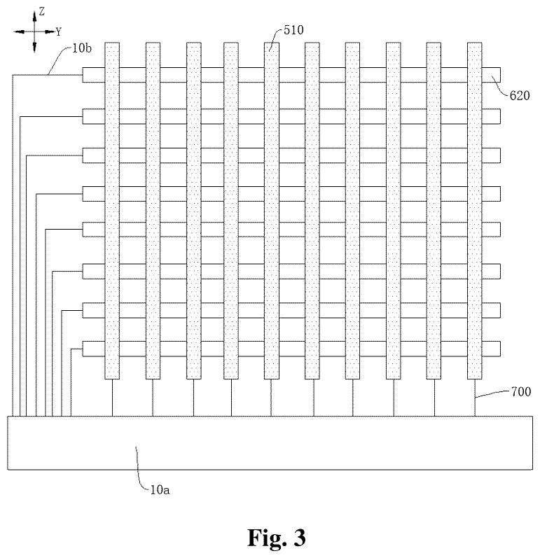

FIG. 3 shows a partial schematic structural diagram of a display module 10 according to an embodiment of the present application.

As shown in FIGS. 2 and 3, in some optional embodiments, the display module 10 includes a touch driving signal line 620 and a touch driving transistor 610 connected with the first electrode 210, the touch driving signal line 620 is configured to transmit the touch driving signal to the first electrode 210 through the touch driving transistor 610, the touch driving transistor 610 includes a first source 612 and a first drain 613, one of the first source 612 and the first drain 613 is connected with the first electrode 210, and the other one of the first source 612 and the first drain 613 is connected with the touch driving signal line 620.

When the touch driving transistor 610 is turned on, i.e., when the first source 612 and the first drain 613 are connected with each other, the touch driving signal line 620 may be electrically connected with the first electrode 210, so that the touch driving signal line 620 may transmit the touch driving signal to the first electrode 210, and an induced capacitor may be formed between the first electrode 210 and the second electrode 510, so as to achieve the touch control function for the display module 10. When the touch driving transistor 610 is turned off, i.e., when the first source 612 and the first drain 613 are disconnected from each other, the electrical connection between the touch driving signal line 620 and the first electrode 210 is also disconnected, so that when the first electrode 210 is required to participate in light emitting and display of the display module 10, the touch driving signal is less likely to interfere with a driving current signal transmitted to the first electrode 210, and thus the display module 10 can have better stability for light emitting and display.

In some optional embodiments, the array base plate 100 may include a first insulation layer 120, a second insulation layer 130 located at a side of the first insulation layer 120 facing the first electrode layer 200, and a third insulation layer 140 located at a side of the second insulation layer 130 away from the first insulation layer 120. Optionally, the array base plate 100 may further include a substrate 110 located at a side of the first insulation layer 120 away from the second insulation layer 130.

Optionally, the touch driving transistor 610 may be arranged in the array base plate 100. Optionally, the touch driving transistor 610 may further include a first gate 611, the first gate 611 may be arranged at a side of the first insulation layer 120 away from the second insulation layer 130, the touch driving signal line 620 may be arranged between the first insulation layer 120 and the second insulation layer 130, and the first source 612 and the first drain 613 may be arranged between the second insulation layer 130 and the third insulation layer 140. Optionally, the touch driving transistor 610 may further include a first active layer 614, which may be arranged at a side of the first gate 611 facing the substrate 110.

In some optional embodiments, the first electrodes 210 are arranged at intervals in the first direction Y and the second direction Z, and the touch driving transistors 610 respectively corresponding to two adjacent first electrodes 210 in the first direction Y are connected with a same touch driving signal line 620.

Optionally, the touch driving transistor 610 corresponding to the first electrode 210 may refer to a touch driving transistor 610 connected with the first electrode 210. Optionally, the touch driving transistors 610 respectively corresponding to two adjacent first electrodes 210 in the first direction Y being connected with a same touch driving signal line 620 may refer to that, for the adjacent first electrodes 210 in the first direction Y, the touch driving transistor 610 connected with one of the adjacent first electrodes 210 and the touch driving transistor 610 connected with the other one of adjacent the first electrodes 210 are connected with a same touch driving signal line 620.

Optionally, the display module 10 may include at least two touch driving signal lines 620, at least two of the touch driving signal lines 620 are arranged at intervals in the second direction Z, and the touch driving transistors 610 respectively corresponding to two adjacent first electrodes 210 in the second direction Z are connected with different touch driving signal lines 620.

Optionally, the touch driving transistors 610 respectively corresponding to two adjacent first electrodes 210 in the second direction Z being connected with different touch driving signal lines 620 may refer to that, for the adjacent first electrodes 210 in the second direction Z, the touch driving transistor 610 connected with one of the adjacent first electrodes 210 and the touch driving transistor 610 connected with the other one of the adjacent first electrodes 210 are respectively connected with different touch driving signal lines 620.

Optionally, a portion of the touch driving signal lines 620 may be formed extending along the first direction Y, so as to be connected with the touch driving transistors 610 respectively corresponding to two adjacent first electrodes 210 in the first direction Y.

Optionally, if two sub-pixels are adjacent in the first direction Y, the two sub-pixels may be considered to be located in a same row, and if two sub-pixels are adjacent in the second direction Z, the two sub-pixels may be considered to be located in a same column.

In these optional embodiments, the touch driving transistors 610 respectively corresponding to two adjacent first electrodes 210 in the first direction Y are connected with a same touch driving signal line 620, so that a single touch driving signal line can provide the touch driving signal to the first electrodes 210 of the sub-pixels located in a same row in the first direction Y simultaneously, so as to control the touch control function of a row of sub-pixels simultaneously, which facilitates the touch control of the display module 10.

In some optional embodiments, the light-emitting unit EL is configured such that the light-emitting unit EL does not emit light when the touch driving transistor 610 connected with the first electrode 210 of the light-emitting unit EL is turned on, so that the first source 612 and the first drain 613 can be connected with each other when the light-emitting unit EL does not emit light, i.e., when the first electrode 210 under the light-emitting portion 410 is not required to participate in light emitting and display of the display module 10, and thus the driving current signal for light emitting and display is less likely to interfere with the touch driving signal, the display module 10 can have better touch control stability.

Optionally, the touch driving transistor 610 is configured such that the touch driving transistor 610 is turned off when the light-emitting portion 410 corresponding to the first electrode 210 connected with the touch driving transistor 610 emits light, so that the first source 612 and the first drain 613 can be disconnected from each other when the light-emitting portion 410 emits light, i.e., when the first electrode 210 under the light-emitting portion 410 is required to participate in light emitting and display of the display module 10, and thus the touch driving signal is less likely to interfere with the driving current signal for light emitting and display, the display module 10 can have better stability for light emitting and display.

Optionally, the light-emitting portion 410 corresponding to the first electrode 210 connected with the touch driving transistor 610 may refer to a light-emitting portion 410 located at a side of the first electrode 210 connected with the touch driving transistor 610 away from the array base plate 100 in the thickness direction X.

As shown in FIG. 2, in some optional embodiments, the display module 10 further includes a driving transistor and a light emitting control transistor 800, the driving transistor and the light emitting control transistor 800 are connected between a power supply voltage signal line VDD and the light-emitting unit EL of the display module, the driving transistor is configured to drive the light-emitting unit EL to emit light, the light emitting control transistor 800 includes a second source 820 and a second drain 830, one of the second source 820 and the second drain 830 is connected with the first electrode 210, the other one of the second source 820 and the second drain 830 is connected with the driving transistor, and the touch driving transistor 610 is configured such that the touch driving transistor 610 is turned on when the light emitting control transistor 800 is turned off.

In the embodiment, light emitting and display of each sub-pixel in the display module 10 may be controlled by the light emitting control transistor 800. When the second source 820 and the second drain 830 are connected, the driving transistor can transmit the driving current signal to the first electrode 210 through the light emitting control transistor 800, so as to cause the sub-pixel to emit light and display. When the second source 820 and the second drain 830 are disconnected, the sub-pixel may not emit light and display.

Optionally, the touch driving transistor 610 may be configured such that the touch driving transistor 610 is turned on when the second source 820 and the second drain 830 of the light emitting control transistor 800 connected with the same first electrode 210 as the touch driving transistor 610 are disconnected. That is, for the touch driving transistor 610 and the light emitting control transistor 800 connected with the first electrode 210 in a same sub-pixel, the first source 612 and the first drain 613 of the touch driving transistor 610 are connected with each other only when the second source 820 and the second drain 830 of the light emitting control transistor 800 are disconnected, so that the touch driving signal is less likely to interfere with the driving current signal when the sub-pixel emits light and displays, and the display module 10 can have better stability for light emitting and display.

Optionally, the light emitting control transistor 800 may be also arranged in the array base plate 100. Optionally, the light emitting control transistor 800 may further include a second gate 810, which may be arranged at a side of the first insulation layer 120 away from the second insulation layer 130, and the second source 820 and the second drain 830 may be arranged between the second insulation layer 130 and the third insulation layer 140. Optionally, the light emitting control transistor 800 may further include a second active layer 840, which may be arranged at a side of the second gate 810 facing the substrate 110.

Optionally, the array base plate 100 may further include a source-drain conductive portion 160 and a fourth insulation layer 150 located at a side of the third insulation layer 140 away from the second insulation layer 130. The source-drain conductive portion 160 may be arranged between the third insulation layer 140 and the fourth insulation layer 150, the first electrode 210 may be connected with the source-drain conductive portion 160 through a via, the source-drain conductive portion 160 may be connected with the first source 612 or the first drain 613 of the touch driving transistor 610 through a via, and the source-drain conductive portion 160 may be connected with the second source 820 or the second drain 830 of the light emitting control transistor 800 through a via.

In some optional embodiments, the display module 10 further includes a light emitting control signal line EM connected with the first gate 611 and the second gate 810 to transmit a light emitting control signal to the touch driving transistor 610 and the light emitting control transistor 800, in which one of the touch driving transistor 610 and the light emitting control transistor 800 is an N-type transistor and the other one is a P-type transistor.

The light emitting control signal line EM can transmit the light emitting control signal to the touch driving transistor 610 and the light emitting control transistor 800, so as to control the first source 612 and the first drain 613 to be connected or disconnected, and to further control the second source 820 and the second drain 830 to be connected or disconnected, and thus the touch control function and the light emitting and display of the display module 10 can be controlled simultaneously.

One of the touch driving transistor 610 and the light emitting control transistor 800 is an N-type transistor and the other one is a P-type transistor, so that the condition for the touch driving transistor 610 to be turned on is different from the condition for the light emitting control transistor 800 to be turned on, i.e., the light emitting control signal required for the touch driving transistor 610 to be turned on is different from the light emitting control signal required for the light emitting control transistor 800 to be turned on, and thus the touch driving transistor 610 and the light emitting control transistor 800 are less likely to be turned on at the same time, and the touch driving signal and the driving current signal are less likely to interfere with each other.

Specifically, for the touch driving transistor 610 and the light emitting control transistor 800 connected with one sub-pixel, the first source 612 and the first drain 613 are connected and the second source 820 and the second drain 830 are disconnected when the light emitting control signal line EM transmits the light emitting control signal with a certain level to the first gate 611 and the second gate 810, so as to implement the touch control operation of the sub-pixel; or the first source 612 and the first drain 613 are disconnected and the second source 820 and the second drain 830 are connected when the light emitting control signal line EM transmits the light emitting control signal with a certain level to the first gate 611 and the second gate 810, so as to implement the light emitting and display operation of the sub-pixel.

For example, the light emitting control transistor 800 may be a P-type transistor, and the touch driving transistor 610 may be an N-type transistor. When the light emitting control signal line EM transmits the light emitting control signal with a high level to the first gate 611 and the second gate 810, the first source 612 and the first drain 613 are connected, and the second source 820 and the second drain 830 are disconnected, so that the touch driving signal can be transmitted to the first electrode 210, while the driving current signal cannot be transmitted to the first electrode 210, so as to implement stable touch control operation of the sub-pixel. When the light emitting control signal line EM transmits the light emitting control signal with a low level to the first gate 611 and the second gate 810, the first source 612 and the first drain 613 are disconnected, and the second source 820 and the second drain 830 are connected, so that the touch driving signal cannot be transmitted to the first electrode 210, while the driving current signal can be transmitted to the first electrode 210, so as to implement stable light emitting and display operation of the sub-pixel.

As shown in FIG. 3, in some optional embodiments, the display module 10 further includes a touch control module 10a and a touch control line 10b, the touch control module 10a is connected with the touch driving signal line 620 through the touch control line 10b, and the touch control module 10a is configured to transmit the touch driving signal to the touch driving transistor 610 through the touch control line 10b and the touch driving signal line 620.

Optionally, a number of the touch control lines 10b is the same as a number of the light emitting control signal lines EM.

Optionally, one light emitting control signal line EM may be connected with the second gates 810 of the light emitting control transistors 800 connected with only one row of sub-pixels, so that one light emitting control signal line EM can control light emitting and display of only one row of sub-pixels. In such case, the number of the light emitting control signal lines EM is equal to the number of rows of the sub-pixels in the display module 10, i.e., the number of the light emitting control signal lines EM is equal to the number of rows of the light-emitting portions 410 or the first electrodes 210.

Optionally, one light emitting control signal line EM may be connected with the second gates 810 of the light emitting control transistors 800 connected with at least two rows of sub-pixels, so that one light emitting control signal line EM can control light emitting and display of a plurality of rows of sub-pixels simultaneously. In such case, the number of the light emitting control signal lines EM is less than the number of rows of the sub-pixels in the display module 10, i.e., the number of the light emitting control signal lines EM is less than the number of rows of the light-emitting portions 410 or the first electrodes 210, so as to better reduce the number of the light emitting control signal lines EM in the display module 10 and facilitate the control of light emitting and display of each sub-pixel in the display module 10.

Optionally, as shown in FIG. 3, one touch control line 10b may be connected with only one touch driving signal line 620, so that one touch control line 10b may transmit the touch driving signal to only one touch driving signal line 620, and thus the touch driving signal may be transmitted to the first electrodes 210 of only one row of sub-pixels through the touch driving transistor 610, so as to achieve the touch control function for one row of sub-pixels. In such case, the number of the touch control lines 10b is equal to the number of rows of the sub-pixels in the display module 10, i.e., the number of the touch control lines 10b is equal to the number of rows of the light-emitting portions 410 or the first electrodes 210.

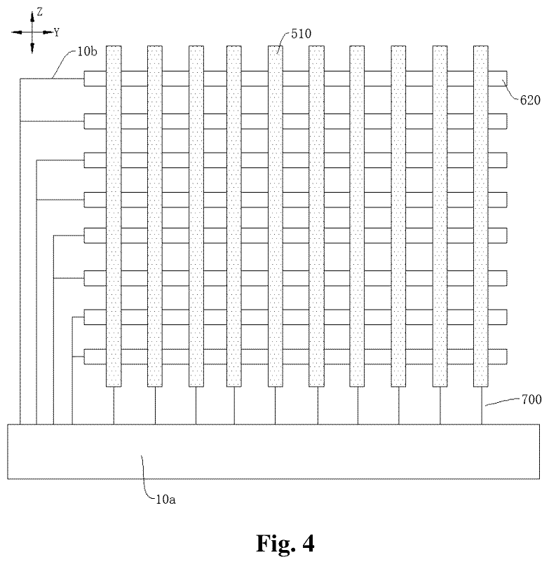

FIG. 4 shows a partial schematic structural diagram of a display module 10 according to an embodiment of the present application.

Optionally, as shown in FIG. 4, one touch control line 10b may be connected with at least two touch driving signal lines 620, so that one touch control line 10b may transmit the touch driving signal to at least two touch driving signal lines 620 simultaneously, and thus the touch driving signal may be transmitted to the first electrodes 210 of a plurality of rows of sub-pixels through the touch driving transistor 610, so as to achieve the touch control function for a plurality of rows of sub-pixels simultaneously. In such case, the number of the touch control lines 10b is less than the number of rows of the sub-pixels in the display module 10, i.e., the number of the touch control lines 10b is less than the number of rows of the light-emitting portions 410 or the first electrode 210, so as to better reduce the number of the touch control lines 10b in the display module 10 and facilitate the control of the touch control operation of each sub-pixel in the display module 10 by the touch control module 10a.

Optionally, when there are at least two touch control lines 10b, the touch control lines 10b may be connected with a same touch control module 10a, and the touch control module 10a may transmit the touch driving signal to one or more of the touch control lines 10b relatively independently.

In these optional embodiments, the number of the touch control lines 10b is the same as the number of the light emitting control signal lines EM, so that the touch control lines 10b and the light emitting control signal lines EM can be in one-to-one correspondence, and thus in the display module 10, the operation for the touch control module 10a to transmit the touch driving signal to the first electrode 210 through the touch control line 10b can be synchronized with the operation for the light emitting control signal to control the touch driving transistor 610 and the light emitting control transistor 800.

For example, the number of the touch control lines 10b is the same as the number of the light emitting control signal lines EM, so that when any light emitting control signal line EM controls the light emitting control transistors 800 connected with the first electrodes 210 of a certain row of sub-pixels to be turned on, the touch control module 10a can stop transmitting the touch driving signal to one touch control line 10b corresponding to the light emitting control signal line EM, so as to stop transmitting the touch driving signal to the touch driving transistors 610 connected with the row of sub-pixels. Therefore, when the row of sub-pixels emit light and display, not only the first source 612 and the first drain 613 of the touch driving transistors 610 connected with the row of sub-pixels are disconnected, but also the touch control line 10b stops transmitting, through the touch driving signal line 620, the touch driving signal to the touch driving transistors 610 connected with the row of sub-pixels, so that the energy consumption of the display module 10 can be better reduced.

Optionally, only when any light emitting control signal line EM controls the light emitting control transistors 800 connected with the first electrodes 210 of a certain row of sub-pixels to be turned off, the touch control module 10a transmits the touch driving signal to one touch control line 10b corresponding to the light emitting control signal line EM to transmit the driving signal to the touch driving transistors 610 connected with the row of sub-pixels, so as to implement the touch control operation of the row of sub-pixels.

As another example, the number of the touch control lines 10b is the same as the number of the light emitting control signal lines EM, so that when any light emitting control signal line EM controls the light emitting control transistors 800 connected with the first electrodes 210 of a plurality of rows of sub-pixels to be turned on, the touch control module 10a can stop transmitting the touch driving signal to one touch control line 10b corresponding to the light emitting control signal line EM, so as to stop transmitting the touch driving signal to the touch driving transistors 610 connected with the plurality of rows of sub-pixels. Therefore, when the plurality of rows of sub-pixels emit light and display, not only the first source 612 and the first drain 613 of the touch driving transistors 610 connected with the plurality of rows of sub-pixels are disconnected, but also the touch control line 10b stops transmitting, through the touch driving signal line 620, the touch driving signal to the touch driving transistors 610 connected with the plurality of rows of sub-pixels, so that the energy consumption of the display module 10 can be better reduced.

Optionally, only when any light emitting control signal line EM controls the light emitting control transistors 800 connected with the first electrodes 210 of a plurality of rows of sub-pixels to be turned off, the touch control module 10a transmits the touch driving signal to one touch control line 10b corresponding to the light emitting control signal line EM to transmit the touch driving signal to the touch driving transistors 610 connected with the plurality of rows of sub-pixels, so as to implement the touch control operation of the plurality of rows of sub-pixels.

In some optional embodiments, the touch control module 10a is further configured to transmit a reset signal to the first electrode 210 through the touch driving signal line 620 and the touch driving transistor 610 to reset the first electrode 210. Optionally, the touch control module 10a may be configured to transmit a reset signal to the touch driving signal line 620. When one or more sub-pixels in the display module 10 enter a non-light emitting stage, the touch control module 10a may transmit a reset signal to the one or more sub-pixels through the touch driving signal line 620, so as to reset the voltage of the first electrode 210.

Optionally, the touch driving signal line 620 may be reused as a reset signal line in the display module, so that the reset signal transmitted from the touch control module 10a may be transmitted to the first electrode 210 through the touch driving signal line 620.

In some embodiments, each light-emitting unit has a display cycle including at least one light emitting stage and at least one non-light emitting stage. Herein, the light-emitting unit can emit light and display in the light emitting stage, and may not emit light and display in the non-light emitting stage. Specifically, the time period corresponding to the display of one frame may be one display cycle.

In one display cycle of the light-emitting unit, the touch control module 10a may transmit the reset signal to the first electrode 210 of the light-emitting unit only when the light-emitting unit is in the first non-light emitting stage, so as to reset the voltage of the first electrode 210. Optionally, in the first non-light emitting stage of the light-emitting unit, after the touch control module 10a transmitting the reset signal to the first electrode 210 of the light-emitting unit, the touch control module 10a may further transmit the touch driving signal to the first electrode 210 of the light-emitting unit in the first non-light emitting stage of the light-emitting unit. Alternatively, the touch control module 10a may transmit the touch driving signal to the first electrode 210 of the light-emitting unit when the light-emitting unit is in a non-light emitting stage after the first non-light emitting stage, so as to achieve touch control function for the sub-pixel corresponding to the light-emitting unit.

As shown in FIG. 3, in some embodiments of the present application, the display module 10 may include a touch sensing signal line 700 connected with the second electrode 510, and the touch sensing signal line 700 is configured to receive a touch sensing signal output by the second electrode 510. Optionally, the touch sensing signal line 700 may be connected with the touch control module 10a, so that the touch control module 10a can acquire a touch sensing signal fed back by the second electrode 510 through the touch sensing signal line 700, so as to detect the change of the induced capacitance between the first electrode 210 and the second electrode 510.

Optionally, the touch sensing signal line 700 is further configured to transmit a negative power supply voltage signal to the second electrode 510 when the light-emitting unit EL emits light.

Optionally, the touch control module 10a may be configured to acquire, through the touch sensing signal line 700, a touch sensing signal fed back by the second electrode 510 when the light-emitting unit does not emit light, so as to detect the change of the induced capacitance between the first electrode 210 and the second electrode 510 in the non-light emitting stage of the light-emitting unit. Optionally, the touch control module 10a may be further configured to transmit, through the touch sensing signal line 700, a negative power supply voltage signal (such as an ELVSS signal) to the second electrode 510 when the light-emitting unit emits light, so as to implement light emitting and display of the light-emitting unit in the light emitting stage of the light-emitting unit.

In some embodiments of the present application, the touch sensing signal line 700 may be connected with the second electrode 510 in various manners.

As shown in FIG. 3, in some optional embodiments, the touch sensing signal line 700 may be directly connected with the second electrode 510. Optionally, at least two second electrodes 510 are arranged at intervals in the first direction Y and formed extending along the second direction Z.

Optionally, the orthographic projections of the light-emitting portions 410 located in a same column on the array base plate 100 may be located within the orthographic projection of a same second electrode 510 on the array base plate 100, so that one touch sensing signal line 700 can acquire the change of the induced capacitance between the first electrode 210 and the second electrode 510 in at least one column of sub-pixels.

Optionally, the orthographic projections of at least two columns of light-emitting portions 410 that are spaced apart and adjacent in the first direction Y on the array base plate 100 may be located within the orthographic projection of a same second electrode 510 on the array base plate 100, or the orthographic projections of at least two columns of first electrodes 210 that are spaced apart and adjacent in the first direction Y on the array base plate 100 may be located within the orthographic projection of a same second electrode 510 on the array base plate 100. Therefore, one touch sensing signal line 700 connected with one second electrode 510 can acquire the change of the induced capacitance between the first electrode 210 and the second electrode 510 in a plurality of columns of sub-pixels simultaneously, so as to better reduce the number of the touch sensing signal lines 700 and facilitate the arrangement of the touch control sensing signal lines 700.

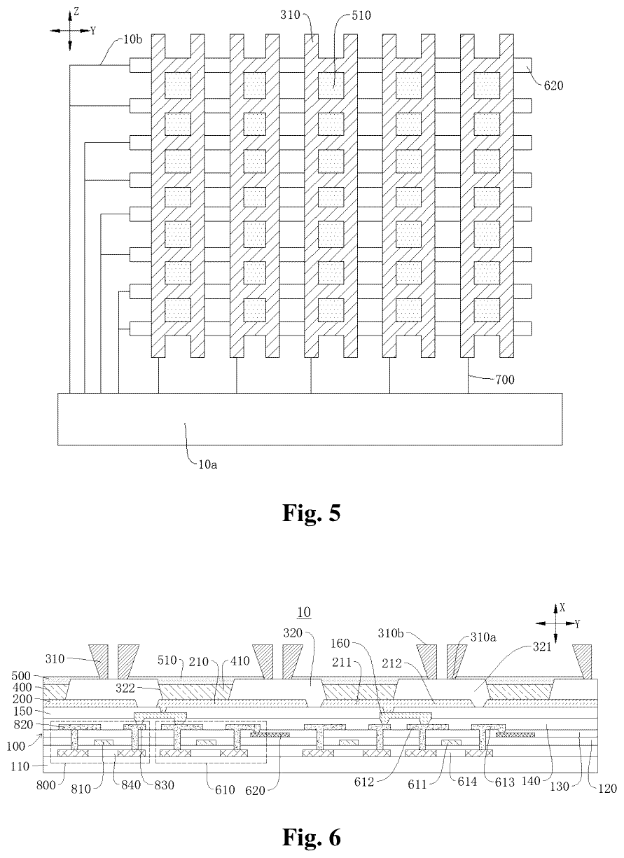

FIG. 5 shows a partial schematic structural diagram of a display module 10 according to yet another embodiment of the present application, and FIG. 6 shows a partial sectional view of a display module 10 according to another embodiment of the present application.

As shown in FIGS. 5 and 6, in some other optional embodiments, the display module further includes at least two isolation structures 310 arranged at intervals in the first direction Y and formed extending along the second direction Z, the isolation structure 310 includes an electrically conductive material, the second electrodes 510 are arranged in different pixel openings 322 respectively, the second electrodes 510 are arranged at intervals in the first direction Y and the second direction Z, and adjacent second electrodes 510 in the second direction Z are electrically connected with each other through the isolation structure 310.

The touch sensing signal line 700 may be connected with the isolation structure 310, so that the touch sensing signal line 700 may be connected with the second electrode 510 through the isolation structure 310. Herein, the touch sensing signal line 700 may be configured to transmit the touch sensing signal to the second electrode 510 through the isolation structure 310.

Optionally, the isolation structure 310 may be arranged around at least a portion of the pixel opening 322, so as to facilitate the connection between the isolation structure 310 and the second electrode 510, and further to better increase the possible connection area between the isolation structure 310 and the second electrode 510.

Optionally, the touch sensing signal line 700 may be connected with the isolation structure 310, so that the touch sensing signal line 700 may be connected with the second electrode 510 through the isolation structure 310. Herein, the touch sensing signal line 700 may be configured to receive a touch sensing signal output by the second electrode 510 through the isolation structure 310, so that one touch sensing signal line 700 can acquire, through the isolation structure 310, the change of the induced capacitance between the first electrode 210 and the second electrode 510 in at least one column of sub-pixels.

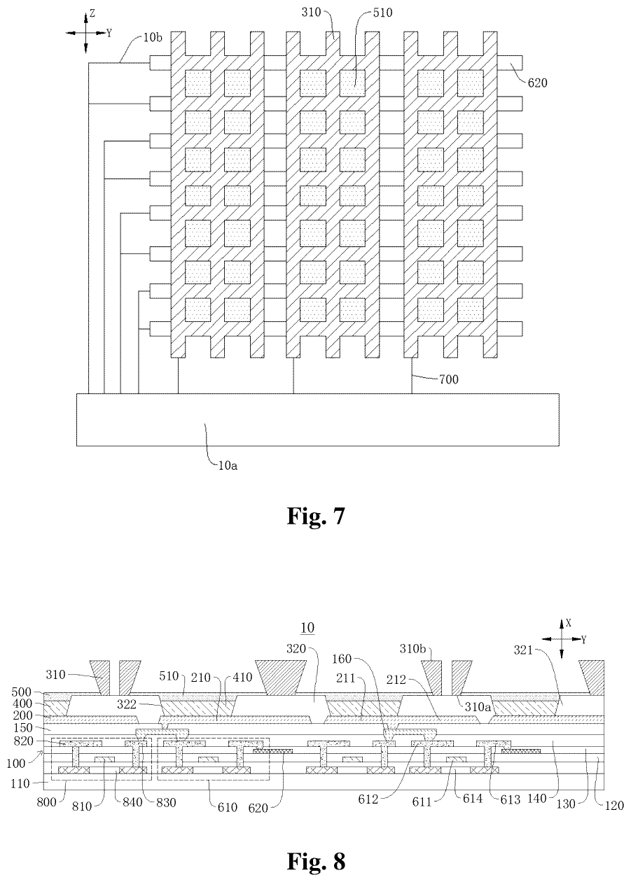

FIG. 7 shows a partial schematic structural diagram of a display module 10 according to yet another embodiment of the present application, and FIG. 8 shows a partial sectional view of a display module 10 according to yet another embodiment of the present application.

As shown in FIGS. 7 and 8, optionally, the isolation structure 310 may be a mesh in shape. Optionally, a portion of the isolation structures 310 may be formed extending along the first direction Y, and a portion of the isolation structures 310 may be formed extending along the second direction Z, so that the isolation structures 310 may be interleaved to form the mesh.

Optionally, a portion of adjacent second electrodes 510 in the first direction Y are connected through the isolation structure 310. Optionally, at least two columns of second electrodes 510 that are spaced apart and adjacent in the first direction Y may be connected with a same isolation structure 310. For example, at least two columns of second electrodes 510 that are spaced apart and adjacent in the first direction Y may be located in a hollow area in the mesh isolation structure 310, so that one touch sensing signal line 700 may simultaneously acquire, through the isolation structure 310, the change of the induced capacitance between the first electrode 210 and the second electrode 510 in at least two columns of sub-pixels.

For ease of description, in the following embodiments, for example, the touch sensing signal line 700 is connected with second electrode 510 through the isolation structure 310.

As shown in FIG. 8, in some optional embodiments, the isolation structure 310 includes a first end portion 310a and a second end portion 310b opposite to each other in the thickness direction X of the display module 10, the second end portion 310b is located at a side of the first end portion 310a away from the array base plate 100, and an orthographic projection of the first end portion 310a on the array base plate 100 is located within an orthographic projection of the second end portion 310b on the array base plate 100.

Optionally, a distance between surfaces of the isolation structure 310 respectively facing the pixel openings 322 located at both sides of the isolation structure 310 gradually increases in a direction away from the array base plate 100, so that the orthographic projection of the first end portion 310a of the isolation structure 310 on the array base plate 100 is located within the orthographic projection of the second end portion 310b of the isolation structure 310 on the array base plate 100.

In these optional embodiments, the orthographic projection of the first end portion 310a of the isolation structure 310 on the array base plate 100 is located within the orthographic projection of the second end portion 310b of the isolation structure 310 on the array base plate 100, so that during vapor deposition of the light-emitting functional layer 400 of the display module 10, the second end portion 310b can block at least a portion of the material for preparing the light-emitting functional layer 400, so as to separate the light-emitting functional layers 400 of adjacent sub-pixels and facilitate forming a plurality of light-emitting portions 410 that are arranged at intervals, and thus no fine mask is required for vapor deposition of the light-emitting functional layer 400 of the display module 10. Therefore, for example, no Fine Metal Mask (FMM) is required for vapor deposition of the light-emitting functional layer 400, thereby reducing the cost for manufacturing the display module 10.

FIG. 9 shows a partial sectional view of a display module 10 according to yet another embodiment of the present application.

As shown in FIG. 9, in some optional embodiments, the isolation structure 310 includes a first isolation portion 311 and a second isolation portion 312 located at a side of the first isolation portion 311 away from the array base plate 100, the second isolation portion 312 protrudes toward the pixel opening 322 from the first isolation portion 311, and an orthographic projection of the first isolation portion 311 on the array base plate 100 is located within an orthographic projection of the second isolation portion 312 on the array base plate 100.

Optionally, the first end portion 310a may be located at the first isolation portion 311, and the second end portion 310b may be located at the second isolation portion 312. Optionally, the second isolation portion 312 may protrudes toward the pixel opening 322 in relative to the first isolation portion 311.

Optionally, the first isolation portion 311 includes an electrically conductive material, and adjacent second electrodes 510 in the second direction Z are connected through the first isolation portion 311.

The orthographic projection of the first isolation portion 311 on the array base plate 100 is located within the orthographic projection of the second isolation portion 312 on the array base plate 100, so that during vapor deposition of the light-emitting functional layer 400 and the second electrode layer 500 of the display module 10, the second isolation portion 312 can block at least a portion of the material for preparing the light-emitting functional layer 400 and the material for preparing the second electrode layer 500, so as to separate the light-emitting functional layers 400 and the second electrode layers 500 of adjacent sub-pixels and facilitate forming a plurality of light-emitting portions 410 and a plurality of second electrodes 510 that are arranged at intervals, and thus no fine mask is required for vapor deposition the light-emitting functional layer 400 and the second electrode layer 500 of the display module 10. Therefore, for example, no Fine Metal Mask is required for vapor deposition of the light-emitting functional layer 400 and the second electrode layer 500, thereby reducing the cost for manufacturing the display module 10.

In some optional embodiments, the relative position between the isolation structure 310 and the pixel definition layer 320 may be arranged in various manners. In some embodiments, as shown in FIG. 8, the isolation structure 310 may be arranged at a side of the pixel definition portion 321 away from the array base plate 100, so that the isolation structure 310 can have a higher height in comparison to the array base plate 100, so as to facilitate separating of the light-emitting functional layers 400 by the isolation structure 310.

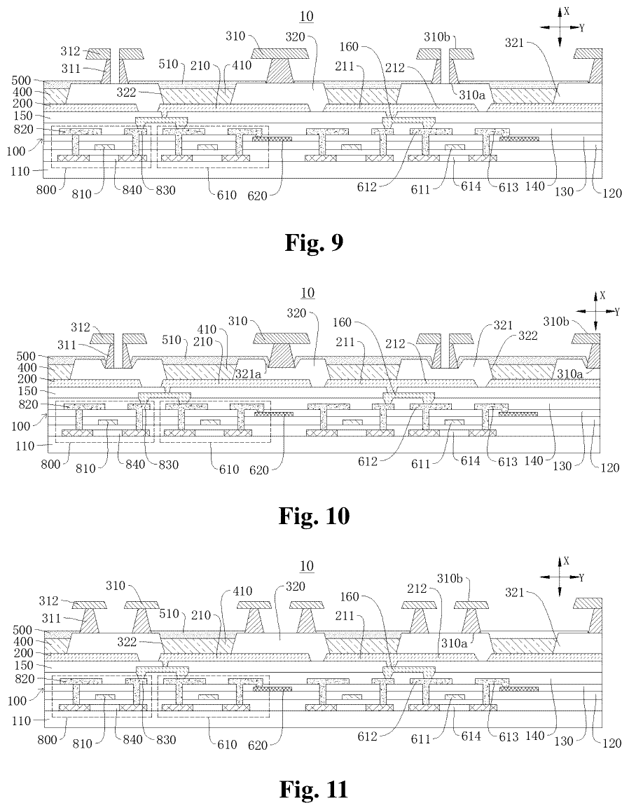

FIG. 10 shows a partial sectional view of a display module 10 according to yet another embodiment of the present application.

As shown in FIG. 10, in some other embodiments, the pixel definition portion 321 includes an accommodating slot, and at least a portion of the isolation structure 310 is located in the accommodating slot 321a, so that the isolation structure 310 will not have an excessively great height in comparison to the array base plate 100, so as to reduce the thickness of the display module 10.

As shown in FIG. 10, optionally, the shape of a surface of the isolation structure 310 located at a side facing the pixel opening 322 may be different from the shape of a surface of the isolation structure 310 located at a side facing a spacing between the isolation structure 310 and an adjacent isolation structure 310, and the specific shape of an inner wall surface of the spacing between adjacent isolation structures 310 may be set according to the manufacturing process requirement or the light transmittance requirement at the spacing, so that the spacing between adjacent isolation structures 310 can be prepared by better manufacturing process and better manufacturing method, or light at an angle within a particular range can better pass the spacing between adjacent isolation structures 310, so as to facilitate the design of the light transmittance of the display module 10.

FIG. 11 shows a partial sectional view of a display module 10 according to yet another embodiment of the present application.

As shown in FIG. 11, in some other embodiments, the shape of the surface of the isolation structure 310 located at the side facing the pixel opening 322 may be the same as the shape of the surface of the isolation structure 310 located at the side facing the spacing between the isolation structure 310 and the adjacent isolation structure 310, so that when preparing the isolation structure 310, the surface of the isolation structure 310 located at the side facing the pixel opening 322 and the surface of the isolation structure 310 located at the side facing the spacing between the isolation structure 310 and the adjacent isolation structure 310 can be prepared in a same manufacturing process, so as to better improve the efficiency for preparing the display module 10.

The embodiments of the second aspect of the present application provide a display apparatus including the display module 10 according to any of the above embodiments of the first aspect. Since the display apparatus according to the embodiments of the second aspect of the present application includes the display module 10 according to any of the above embodiments of the first aspect, the display apparatus has the beneficial effect of the display module 10, which will not be repeated herein.

The display apparatus in the embodiments of the present application includes, but is not limited to, a cellular phone, a Personal Digital Assistant (PDA), a tablet computer, an e-book, a television, an entrance guard, a smart fixed-line phone, a console, and other apparatus with display function.

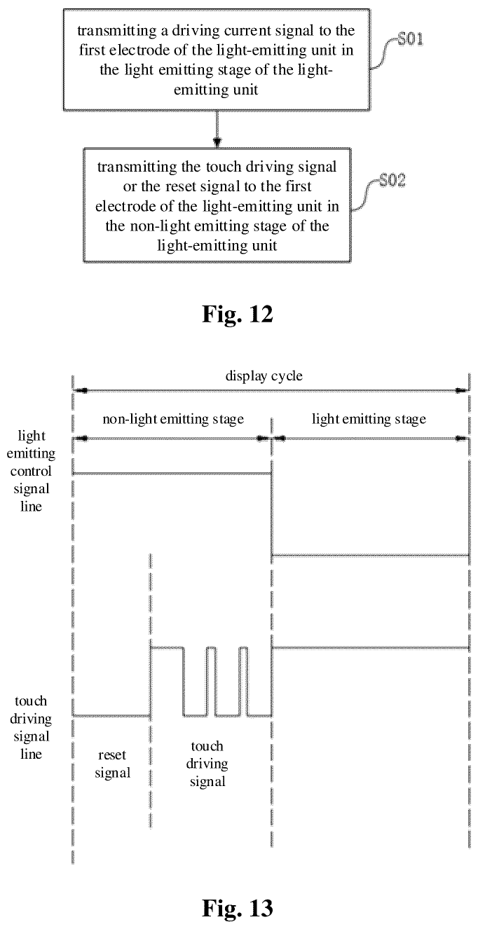

FIG. 12 shows a schematic flow chart of a driving method for a display module 10 according to an embodiment of the present application, and FIG. 13 shows a schematic sequence chart of a driving method for a display module 10 according to an embodiment of the present application.

Referring to FIGS. 12 and 13 and FIGS. 1 to 11, the embodiments of the third aspect of the present application provide a driving method for the display module 10 according to any of the above implementation, each light-emitting unit has a display cycle including at least one light emitting stage and at least one non-light emitting stage, and the driving method includes:

Step S01: transmitting a driving current signal to the first electrode 210 of the light-emitting unit in the light emitting stage of the light-emitting unit; and

Step S02: transmitting the touch driving signal or the reset signal to the first electrode 210 of the light-emitting unit in the non-light emitting stage of the light-emitting unit.

In the driving method according to the present application, the touch driving signal or the reset signal are transmitted to the first electrode 210 of the light-emitting unit only in the non-light emitting stage of the light-emitting unit, so that the driving current signal is less likely to interfere with the touch driving signal and the reset signal, and thus the display module 10 can have better stability for light emitting and display, as well as touch control.

In some optional embodiments, step S02 further includes:

Step S021: as shown in FIG. 13, transmitting the reset signal to the first electrode 210 of the light-emitting unit in a first non-light emitting stage in the display cycle of the light-emitting unit.

Optionally, in the first non-light emitting stage in the display cycle of the light-emitting unit, the touch control module 10a may transmit the reset signal to the first electrode 210 through the touch control line 10b, the touch driving signal line 620, and the touch driving transistor 610, so as to reset the first electrode 210.

Optionally, step S021 may further include:

Step S0211: as shown in FIG. 13, transmitting the reset signal and the touch driving signal to the first electrode 210 of the light-emitting unit in sequence in the first non-light emitting stage in the display cycle of the light-emitting unit.

With step S0211, in the first non-light emitting stage of the light-emitting unit, after the touch control module 10a transmitting the reset signal to the first electrode 210 of the light-emitting unit, the touch control module 10a may further transmit the touch driving signal to the first electrode 210 of the light-emitting unit in the first non-light emitting stage of the light-emitting unit.

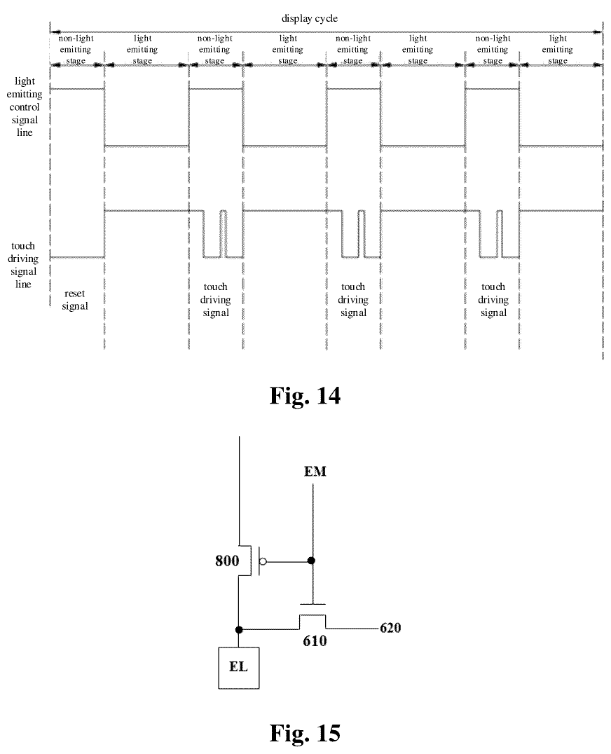

FIG. 14 shows a schematic sequence chart of a driving method for a display module according to another embodiment of the present application.

Optionally, the display cycle includes at least two non-light emitting stages, and step S021 may further include:

Step S022: as shown in FIG. 14, transmitting the touch driving signal to the first electrode 210 of the light-emitting unit in a non-light emitting stage after a first non-light emitting stage in the display cycle of the light-emitting unit.

Optionally, in the non-light emitting stage after the first non-light emitting stage in the display cycle of the light-emitting unit, the touch control module 10a may transmit the touch driving signal to the first electrode 210 through the touch control line 10b, the touch driving signal line 620, and the touch driving transistor 610.

The reset signal is transmitted to the first electrode 210 in the first non-light emitting stage in the display cycle to reset the first electrode 210, so that in the non-light emitting stage after the first non-light emitting stage in the display cycle, the touch driving signal is less likely to be affected by the residual driving current signal in the first electrode 210, and thus the display module 10 has better touch control stability.

In some optional embodiments, when the light-emitting unit is switched from the non-light emitting stage to the light emitting stage, a state for transmitting the reset signal to the first electrode 210 of the light-emitting unit is switched to a state for stopping transmitting the reset signal to the first electrode 210 of the light-emitting unit, or a state for transmitting the touch driving signal to the first electrode 210 of the light-emitting unit is switched to a state for stopping transmitting the touch driving signal to the first electrode 210 of the light-emitting unit.

Optionally, when the light-emitting unit is switched from the non-light emitting stage to the light emitting stage, the state for transmitting the reset signal to the first electrode 210 of the light-emitting unit being switched to the state for stopping transmitting the reset signal to the first electrode 210 of the light-emitting unit may refer to that when the light-emitting unit is switched from the non-light emitting stage to the light emitting stage, i.e., when the level of the light emitting control signal changes, and for example, when the light emitting control signal changes from a high level to a low level, the touch control module 10a stops transmitting the reset signal to the first electrode 210 of the light-emitting unit.

Optionally, the reset signal may be a constant potential signal. Optionally, the reset signal may be a constant low level signal.

Optionally, when the light-emitting unit is switched from the non-light emitting stage to the light emitting stage, the state for transmitting the touch driving signal to the first electrode 210 of the light-emitting unit being switched to the state for stopping transmitting the touch driving signal to the first electrode 210 of the light-emitting unit may refer to that when the light-emitting unit is switched from the non-light emitting stage to the light emitting stage, i.e., when the level of the light emitting control signal changes, and for example, when the light emitting control signal changes from a high level to a low level, the touch control module 10a stops transmitting the touch driving signal to the first electrode 210 of the light-emitting unit.

Optionally, the touch driving signal is a pulse signal. The touch driving signal may be a low level signal at the moment when the light emitting control signal changes from a high level to a low level.

Optionally, a lowest potential of the reset signal is the same as a lowest potential of the touch driving signal.

In these optional embodiments, at the moment when the light emitting control signal changes from a high level to a low level, the lowest potential of the reset signal may be the same as the lowest potential of the touch driving signal, and the reset signal may be a low level signal, so that the sub-pixel is less likely to flicker.

FIG. 15 shows a schematic structural diagram of a pixel circuit according to an embodiment of the present application.

Referring to FIGS. 12 to 15 and FIGS. 1 to 11, the embodiments of the fourth aspect of the present application provide a pixel circuit that may be applied in the display module 10 according to any of the above embodiments.

The pixel circuit includes: a light-emitting unit EL; a light emitting control transistor 800 connected with the light-emitting unit EL; and a touch driving transistor 610 connected with the light-emitting unit EL, in which in a light emitting stage, the touch driving transistor 610 is turned off, and the light emitting control transistor 800 is turned on to control the light-emitting unit EL to emit light; in a non-light emitting stage, the light emitting control transistor 800 is turned off, and the touch driving transistor 610 is turned on and transmits a touch driving signal to the light-emitting unit EL.

In the pixel circuit according to the embodiments of the present application, the light emitting control signal line EM may be the light emitting control signal line EM according to any of the above implementation.

Optionally, the light-emitting unit EL includes a first electrode 210, a light-emitting portion 410, and a second electrode 510 that are stacked, the light emitting control transistor 800 may be connected with the first electrode 210 to control the light-emitting unit EL to emit light, and the touch driving transistor 610 may be connected with the first electrode 210 and configured to transmit the touch driving signal to the first electrode 210. Optionally, the non-light emitting stage may refer to a non-light emitting stage of the light-emitting unit EL. For example, in the non-light emitting stage of the light-emitting unit EL, the light-emitting portion 410 in the light-emitting unit EL may not emit light and display. Optionally, the light-emitting unit EL may further have a light emitting stage, in which the light-emitting portion 410 in the light-emitting unit EL may emit light and display under a condition that the light emitting control transistor 800 is turned on.

Optionally, the light-emitting unit EL in the pixel circuit according to the embodiments may be the light-emitting unit EL according to any of the above embodiments. Optionally, the touch driving transistor 610 in the pixel circuit according to the embodiments may be the touch driving transistor 610 according to any of the above embodiments. Optionally, the light emitting control transistor 800 in the pixel circuit according to the embodiments may be the light emitting control transistor 800 according to any of the above embodiments.

Both the light emitting control transistor 800 and the touch driving transistor 610 are connected with the first electrode 210, so that when the pixel circuit is applied in the display module, the first electrode 210 not only can be used as a pixel electrode of the display module for participating in light emitting and display of the display module, but also can be reused as a touch electrode of the display module for achieving touch control function for the display module.

In some optional embodiments, the pixel circuit further includes a light emitting control signal line EM connected with a control end of the light emitting control transistor 800 and a control end of the touch driving transistor 610, and the light emitting control signal line EM is configured to transmit a light emitting control signal to the light emitting control transistor 800 and the touch driving transistor 610.

The light emitting control signal line EM can control the touch driving transistor 610 and the light emitting control transistor 800 simultaneously by transmitting the light emitting control signal to the touch driving transistor 610 and the light emitting control transistor 800. Herein, in the non-light emitting stage, the light emitting control signal may control the light emitting control transistor 800 to be turned off, so as to control the light-emitting unit EL not to emit light; moreover, the light emitting control signal may control the touch driving transistor 610 to be turned on, so that the touch driving signal may be transmitted to the light-emitting unit EL, and thus in the non-light emitting stage, the light-emitting unit EL may be affected by the touch driving signal to perform touch control operation, and the light-emitting unit EL is less likely to be affected by the driving current signal for driving light emission. That is, when the first electrode 210 in the light-emitting unit EL participates in touch control operation of the display module, the first electrode 210 is less likely to be interfered by the driving current signal.

Optionally, one of the light emitting control transistor 800 and the touch driving transistor 610 is an N-type transistor and the other one is a P-type transistor, so that the condition for the light emitting control transistor 800 to be turned on is different from the condition for the touch driving transistor 610 to be turned on, i.e., the light emitting control signal required for the light emitting control transistor 800 to be turned on is different from the light emitting control signal required for the touch driving transistor 610 to be turned on, so that the light emitting control transistor 800 and the touch driving transistor 610 will not be turned on at the same time, and thus the touch driving signal to be transmitted to the light-emitting unit EL and the driving current signal are less likely to interfere with each other.

Specifically, for the light emitting control transistor 800 and the touch driving transistor 610 connected with one light-emitting unit EL, when the light emitting control signal line EM transmits the light emitting control signal with a certain level to the control end of the light emitting control transistor 800 and the control end of the touch driving transistor 610, the touch driving transistor 610 may be turned on, while the light emitting control transistor 800 may be turned off, so that the light-emitting unit EL can participate in the touch control operation; or when the light emitting control signal line EM transmits the light emitting control signal with a certain level to the control end of the light emitting control transistor 800 and the control end of the touch driving transistor 610, the touch driving transistor 610 may be turned off, while the light emitting control transistor 800 may be turned on, so that the light-emitting unit EL can emit light and display.

For example, the light emitting control transistor 800 may be a P-type transistor, and the touch driving transistor 610 may be an N-type transistor. When the light emitting control signal line EM transmits the light emitting control signal with a high level to the control end of touch driving transistor 610 and the control end of the light emitting control transistor 800, the touch driving transistor 610 is turned on and the light emitting control transistor 800 is turned off, so that the touch driving signal may be transmitted to the first electrode 210, while the driving current signal for driving light emission is not transmitted to the first electrode 210, so as to achieve stable touch control operation for the light-emitting unit EL. When the light emitting control signal line EM transmits the light emitting control signal with a low level to the control end of touch driving transistor 610 and the control end of the light emitting control transistor 800, the touch driving transistor 610 is turned off and the light emitting control transistor 800 is turned on, so that the touch driving signal cannot be transmitted to the first electrode 210, while the driving current signal for driving light emission may be transmitted to the first electrode 210, so as to achieve stable light emitting and display operation for the light-emitting unit EL.

In some optional embodiments, the pixel circuit further includes a touch driving signal line 620, a first end of the touch driving transistor 610 is connected with the touch driving signal line 620, a second end of the touch driving transistor 610 is connected with the light-emitting unit EL, and the touch driving signal line 620 is configured to transmit the touch driving signal to the light-emitting unit EL through the touch driving transistor 610.

In these optional embodiments, the touch driving signal line 620 is configured to transmit the touch driving signal and connected with the touch driving transistor 610, so that the touch driving signal line 620 can transmit the touch driving signal to the first electrode 210 through the touch driving transistor 610, and the first electrode 210 can be further reused as a touch driving electrode in a display module. Optionally, the second electrode 510 in the light-emitting unit EL may be reused as a touch sensing electrode of the display module.

Optionally, the touch driving signal line 620 is further configured to transmit the reset signal to the light-emitting unit EL through the touch driving transistor 610, so that when one or more sub-pixels in the display module enter a non-light emitting stage, the touch driving signal line 620 can not only transmit the touch driving signal to the first electrode 210 through the touch driving transistor 610, but also transmit the reset signal to the first electrode 210 of the one or more sub-pixels through the touch driving transistor 610, so as to reset the voltage of the first electrode 210.

In some optional embodiments, in the non-light emitting stage, the touch driving transistor 610 is turned on and transmits the touch driving signal or the reset signal to the light-emitting unit EL. In the non-light emitting stage, i.e., when the light emitting control signal controls the light emitting control transistor 800 to be turned off to control the light-emitting unit EL not to emit light, the light emitting control signal can control the touch driving transistor 610 to be turned on, so that the touch driving transistor 610 can transmit the touch driving signal or the reset signal to the light-emitting unit EL. Therefore, in the non-light emitting stage, the light-emitting unit EL may be affected only by the touch driving signal or the reset signal, but is less likely to be interfered by the driving current signal for driving light emission.

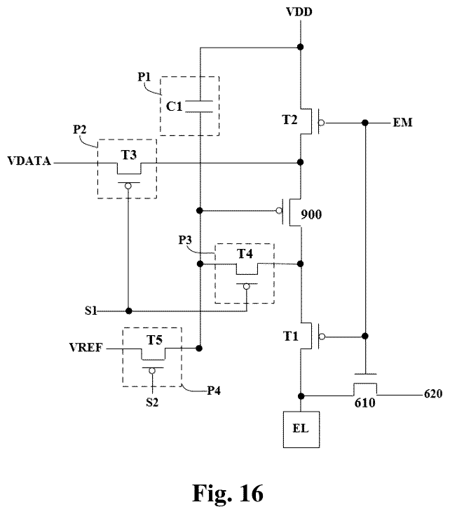

FIG. 16 shows a schematic structural diagram of a pixel circuit according to another embodiment of the present application.

As shown in FIG. 16, in some optional embodiments, the pixel circuit further includes a power supply voltage signal line VDD and a driving transistor 900, and the light emitting control transistor 800 includes a first control transistor T1 and a second control transistor T2, in which the light emitting control signal line EM is connected with control ends of the first control transistor T1 and the second control transistor T2, a first end of the second control transistor T2 is connected with the power supply voltage signal line VDD, a second end of the second control transistor T2 is connected with a first end of the driving transistor 900, a first end of the first control transistor T1 is connected with a second end of the driving transistor 900, and a second end of the first control transistor T1 is connected with the light-emitting unit EL.

Optionally, the pixel circuit further includes an initialization module P4, a storage module P1, a data writing module P2, and a compensation module P3. The initialization module P4 is connected with a control end of the driving transistor 900 and configured to initialize the control end of the driving transistor 900. The storage module P1 is connected with the control end of the driving transistor 900 and configured to maintain the potential of the control end of the driving transistor 900. The data writing module P2 is connected with a data signal end VDATA, a first scanning signal end S1, and a first end of the driving transistor 900, and the data writing module P2 is configured to transmit a data signal to the driving transistor 900. The driving transistor 900 is configured to generate the driving current signal according to the data signal, so as to drive the light-emitting unit EL to emit light. The compensation module P3 is connected with the storage module P1, a second end of the driving transistor 900, and the first scanning signal end S1, and the compensation module P3 is configured to perform threshold compensation on the driving transistor 900.

Optionally, the initialization module P4 includes an initialization transistor T5, the storage module P1 includes a first capacitor C1, the data writing module P2 includes a data writing transistor T3, and the compensation module P3 includes a compensation transistor T4, in which a control end of the initialization transistor T5 is connected with a second scanning signal end S2, a first end of the initialization transistor T5 is connected with an initialization signal end VREF, and a second end of the initialization transistor T5 is connected with the control end of the driving transistor 900; a control end of the data writing transistor T3 is connected with the first scanning signal end S1, a first end of the data writing transistor T3 is connected with the data signal end VDATA, and a second end of the data writing transistor T3 is connected with the first end of the driving transistor 900; a control end of the compensation transistor T4 is connected with the first scanning signal end S1, and a first end of the compensation transistor T4 is connected with the second end of the driving transistor 900; a first end of the first capacitor C1 is connected with the power supply voltage signal line VDD, and a second end of the first capacitor C1 is connected with the control end of the driving transistor 900 and a second end of the compensation transistor T4.

Optionally, the non-light emitting stage may include an initialization stage and a data writing stage, in which in the initialization stage, the initialization module P4 is turned on and initializes the control end of the driving transistor 900; and in the data writing stage, the data writing module P2 and the compensation module P3 are turned on, and the data signal provided by the data signal end VDATA is transmitted to the control end of the driving transistor 900 through the data writing module P2, the driving transistor 900 and the compensation module P3.

Optionally, in the light emitting stage, the light emitting control signal controls the first control transistor T1 and the second control transistor T2 to be turned on, and the driving transistor 900 provides a driving current signal to the light-emitting unit EL through the first control transistor T1 to cause the light-emitting unit EL to emit light.

In these optional embodiments, the initialization module P4 is connected with the second scanning signal end S2 which can be configured to control the initialization module P4 to be turned on or off, so as to control the initialization module P4 to transmit the initialization signal to the driving transistor 900 to initialize the control end of the driving transistor 900. Optionally, the initialization signal and the reset signal transmitted by the touch driving signal line 620 may be similar signals, both of which may perform initialization function or reset function on the device. Specifically, the second scanning signal end S2 is configured to provide a second scanning signal, which includes an enable signal for controlling the initialization transistor T5 of the initialization module P4 to be turned on and a disable signal for controlling the initialization transistor T5 to be turned off. In an initialization stage of the process of driving the light-emitting unit EL of the sub-pixel in the display module by the pixel circuit, the enable signal provided by the second scanning signal can turn on the initialization transistor T5, so that the initialization module P4 may transmit the initialization signal to the control end of the driving transistor 900, so as to initialize the control end of the driving transistor 900.

The data writing module P2 is connected with the data signal end VDATA, the first scanning signal end S1, and the first end of the driving transistor 900; the compensation module P3 is connected with the control end of the driving transistor 900, the second end of the driving transistor 900, and the first scanning signal end S1. Specifically, the data signal end VDATA is configured to provide the data signal. The first scanning signal end S1 is configured to provide a first scanning signal, which includes an enable signal for controlling the data writing transistor T3 of the data writing module P2 and the compensation transistor T4 of the compensation module P3 to be turned on and a disable signal for controlling the data writing transistor T3 and the compensation transistor T4 to be turned off. In a data writing stage of the process of driving the light-emitting unit EL of the sub-pixel in the display module by the pixel circuit, the disable signal provided by the second scanning signal can turn off the initialization transistor T5, and the enable signal provided by the first scanning signal can turn on the data writing transistor T3 and the compensation transistor T4, so that the data signal provided by the data signal end VDATA is transmitted to the control end of the driving transistor 900 through the data writing module P5, the driving transistor 900, and the compensation module P3.

The storage module P1 can store electric energy. In a light emitting stage of the process of driving the light-emitting unit EL of the sub-pixel in the display module by the pixel circuit, the disable signal provided by the second scanning signal can turn off the initialization transistor T5, and the disable signal provided by the first scanning signal can turn off the data writing transistor T3 and the compensation transistor T4. In such case, the storage module P1 can better maintain the potential of the control end of the driving transistor 900.

Optionally, in the non-light emitting stage, the initialization stage may be before the data writing stage, so that the data writing module P2 writes the data signal to the control end of the driving transistor 900 in the data writing stage, and the compensation module P3 charges the storage module P1 using the data signal.

Optionally, in the initialization stage and the data writing stage, the light emitting control signal controls the touch driving transistor 610 to transmit the touch driving signal or the reset signal to the light-emitting unit EL, i.e., in the whole non-light emitting stage, the touch driving transistor 610 may keep to be turned on to transmit the touch driving signal or the reset signal to the light-emitting unit EL, so as to increase the duration for the first electrode 210 in the light-emitting unit EL to participate in the touch control operation, or enable the reset signal to have a better effective duration for the light-emitting unit EL to better reset the light-emitting unit EL.

In the embodiments of the present application, the driving method according to any of the embodiments in the third aspect may be applied by the pixel circuit for driving. For example, the time sequence in which the touch driving transistor 610 transmits the touch driving signal or the reset signal to the light-emitting unit EL may refer to the driving method according to any of the embodiments in the third aspect, which will not be repeated herein.

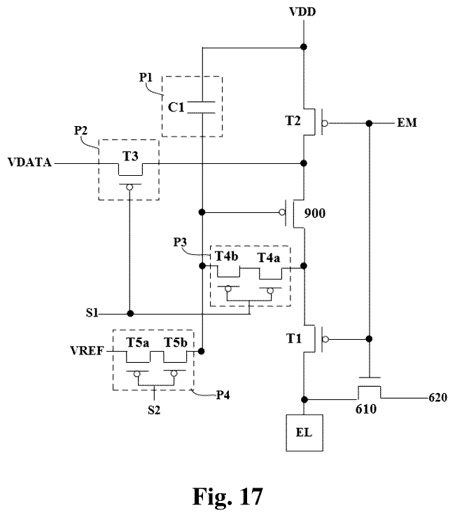

FIG. 17 shows a schematic structural diagram of a pixel circuit according to another embodiment of the present application.

As shown in FIG. 17, optionally, the compensation transistor T4 may include a first sub-transistor T4a and a second sub-transistor T4b, both a control end of the first sub-transistor T4a and a control end of the second sub-transistor T4b are connected with the first scanning signal end S1, a first end of the first sub-transistor T4a is connected with the second end of the driving transistor 900, a second end of the first sub-transistor T4a is connected with a first end of the second sub-transistor T4b, and a second end of the second sub-transistor T4b is connected with the second end of the first capacitor C1 and the control end of the driving transistor 900. With the first sub-transistor T4a and the second sub-transistor T4b, the data signal is less likely to be lost at the compensation module P3, so that the working reliability of the pixel circuit can be improved.

Optionally, the initialization transistor T5 may include a third sub-transistor T5a and a fourth sub-transistor T5b, both a control end of the third sub-transistor T5a and a control end of the fourth sub-transistor T5b are connected with the second scanning signal end S2, a first end of the third sub-transistor T5a is connected with the initialization signal end VREF, a second end of the third sub-transistor T5a is connected with a first end of the fourth sub-transistor T5b, and a second end of the fourth sub-transistor T5b is connected with the control end of the driving transistor 900. With the third sub-transistor T5a and the fourth sub-transistor T5b, the initialization signal is less likely to be lost at the initialization module P4, so that the working reliability of the pixel circuit can be improved.

The above embodiments of the present application do not exhaustively describe all the details, nor do they limit the present application to the specific embodiments as described. Obviously, according to the above description, many modifications and changes can be made. These embodiments are selected and particularly described in the specification to better explain the principles and practical applications of the present application, so that a person skilled in the art is able to utilize the present application and make modifications based on the present application. The present application is limited only by the claims and the full scope and equivalents of the claims.

What is claimed is:

1. A display module, comprising:
an array base plate;
a light-emitting unit arranged at a side of the array base plate and comprising a first electrode located in a first electrode layer, a second electrode located in a second electrode layer, and a light-emitting portion located in a light-emitting functional layer, the second electrode being located at a side of the first electrode away from the array base plate, and the light-emitting portion being located between the second electrode and the first electrode; and
a pixel definition layer arranged at a side of the array base plate, the pixel definition layer comprising a pixel definition portion and a pixel opening defined by the pixel definition portion, and at least a portion of the first electrode being exposed from the pixel opening,
wherein one of the first electrode and the second electrode is configured to receive a touch driving signal, and the other one of the first electrode and the second electrode is configured to output a touch sensing signal.

2. The display module according to claim 1, wherein at least a portion of an orthographic projection of the first electrode on the array base plate is staggered with an orthographic projection of the second electrode on the array base plate;
each first electrode comprises a first portion exposed from the pixel opening and a second portion located between the pixel definition portion and the array base plate, and at least a portion of an orthographic projection of the second portion on the array base plate is staggered with the orthographic projection of the second electrode on the array base plate; and
the second portion is located at at least one side of the first portion in a first direction or a second direction.

3. The display module according to claim 1, wherein the display module comprises a touch driving signal line and a touch driving transistor connected with the first electrode, the touch driving signal line is configured to transmit the touch driving signal to the first electrode through the touch driving transistor, the touch driving transistor comprises a first source and a first drain, one of the first source and the first drain is connected with the first electrode, and the other one of the first source and the first drain is connected with the touch driving signal line.

4. The display module according to claim 3, wherein the touch driving transistor further comprises a first gate, the array base plate comprises a first insulation layer, a second insulation layer located at a side of the first insulation layer facing the first electrode layer, and a third insulation layer located at a side of the second insulation layer away from the first insulation layer, the first gate is arranged at a side of the first insulation layer away from the second insulation layer, the touch driving signal line is arranged between the first insulation layer and the second insulation layer, and the first source and the first drain are arranged between the second insulation layer and the third insulation layer;
the first electrodes are arranged at intervals in a first direction and a second direction, and the touch driving transistors respectively corresponding to two adjacent first electrodes in the first direction are connected with a same touch driving signal line; and
the display module comprises at least two touch driving signal lines, at least two of the touch driving signal lines are arranged at intervals in the second direction, and the touch driving transistors respectively corresponding to two adjacent first electrodes in the second direction are connected with different touch driving signal lines.

5. The display module according to claim 3, wherein the light-emitting unit is configured such that the light-emitting unit does not emit light when the touch driving transistor connected with the first electrode of the light-emitting unit is turned on;
the touch driving transistor is configured such that the touch driving transistor is turned off when the light-emitting portion corresponding to the first electrode connected with the touch driving transistor emits light.

6. The display module according to claim 3, wherein the display module further comprises a driving transistor and a light emitting control transistor, the driving transistor and the light emitting control transistor are connected between a power supply voltage signal line and the light-emitting unit of the display module, the driving transistor is configured to drive the light-emitting unit to emit light, the light emitting control transistor comprises a second source and a second drain, one of the second source and the second drain is connected with the first electrode, the other one of the second source and the second drain is connected with the driving transistor, and the touch driving transistor is configured such that the touch driving transistor is turned on when the light emitting control transistor is turned off.

7. The display module according to claim 6, wherein the display module further comprises a light emitting control signal line, the touch driving transistor further comprises the first gate, the light emitting control transistor further comprises a second gate, and the light emitting control signal line is connected with the first gate and the second gate to transmit a light emitting control signal to the touch driving transistor and the light emitting control transistor, wherein one of the touch driving transistor and the light emitting control transistor is an N-type transistor, and the other one is a P-type transistor.

8. The display module according to claim 7, wherein the display module further comprises a touch control module and a touch control line, the touch control module is connected with the touch driving signal line through the touch control line, and the touch control module is configured to transmit the touch driving signal to the touch driving transistor through the touch control line and the touch driving signal line.

9. The display module according to claim 8, wherein a number of the touch control lines is the same as a number of the light emitting control signal lines; and
the touch driving signal line is further configured to transmit a reset signal to the first electrode through the touch driving transistor to reset the first electrode.

10. The display module according to claim 1, wherein at least two second electrodes are arranged at intervals in a first direction and formed extending along a second direction, wherein the first direction intersects with the second direction.

11. The display module according to claim 1, wherein the display module comprises a touch sensing signal line connected with the second electrode, and the touch sensing signal line is configured to receive a touch sensing signal output by the second electrode; and
the touch sensing signal line is further configured to transmit a negative power supply voltage signal to the second electrode when the light-emitting unit emits light.

12. The display module according to claim 1, wherein the display module further comprises at least two isolation structures arranged at intervals in a first direction and formed extending along a second direction, the isolation structure comprises an electrically conductive material, the second electrodes are arranged at intervals in the first direction and the second direction, and adjacent second electrodes in the second direction are electrically connected with each other through the isolation structure;
the isolation structure is arranged around at least a portion of the pixel opening;
the display module comprises a touch sensing signal line electrically connected with the isolation structure, and the touch sensing signal line is configured to receive a touch sensing signal output by the second electrode through the isolation structure;
the isolation structure comprises a first end portion and a second end portion opposite to each other in a thickness direction of the display module, the second end portion is located at a side of the first end portion away from the array base plate, and an orthographic projection of the first end portion on the array base plate is located within an orthographic projection of the second end portion on the array base plate;
the isolation structure comprises a first isolation portion and a second isolation portion located at a side of the first isolation portion away from the array base plate, the second isolation portion protrudes toward the pixel opening from the first isolation portion, and an orthographic projection of the first isolation portion on the array base plate is located within an orthographic projection of the second isolation portion on the array base plate;
the first isolation portion comprises an electrically conductive material, and adjacent second electrodes in the second direction are connected through the first isolation portion.

13. The display module according to claim 12, wherein the touch sensing signal line is further configured to transmit a negative power supply voltage signal to the second electrode when the light-emitting unit emits light.

14. The display module according to claim 12, wherein the isolation structure is a mesh in shape, and a portion of adjacent second electrodes in the first direction are connected through the isolation structure.

15. The display module according to claim 12, wherein the isolation structure is arranged at a side of the pixel definition portion away from the array base plate, or the pixel definition portion comprises an accommodating slot, and at least a portion of the isolation structure is located in the accommodating slot.

16. The display module according to claim 11, wherein the display module further comprises a touch control module, the touch sensing signal line is connected with the touch control module, and the touch control module is configured to acquire, through the touch sensing signal line, a touch sensing signal fed back by the second electrode when the light-emitting unit does not emit light.

17. The display module according to claim 16, wherein the touch control module is configured to transmit a negative power supply voltage signal to the second electrode through the touch sensing signal line when the light-emitting unit emits light.

18. A driving method for the display module according to claim 1, wherein each light-emitting unit has a display cycle comprising at least one light emitting stage and at least one non-light emitting stage, and the driving method comprises:
transmitting a driving current signal to the first electrode of the light-emitting unit in the light emitting stage of the light-emitting unit; and
transmitting the touch driving signal or the reset signal to the first electrode of the light-emitting unit in the non-light emitting stage of the light-emitting unit.

19. The driving method according to claim 18, wherein the display cycle comprises at least one non-light emitting stage, and the transmitting the touch driving signal or the reset signal to the first electrode of the light-emitting unit in the non-light emitting stage of the light-emitting unit further comprises:
transmitting the reset signal to the first electrode of the light-emitting unit in a first non-light emitting stage in the display cycle of the light-emitting unit.

20. The driving method according to claim 19, wherein the transmitting the reset signal to the first electrode of the light-emitting unit in the first non-light emitting stage in the display cycle of the light-emitting unit further comprises:
transmitting the reset signal and the touch driving signal to the first electrode of the light-emitting unit in sequence in the first non-light emitting stage in the display cycle of the light-emitting unit;
the display cycle comprises at least two non-light emitting stages, and the transmitting the touch driving signal or the reset signal to the first electrode of the light-emitting unit in the non-light emitting stage of the light-emitting unit further comprises:
transmitting the touch driving signal to the first electrode of the light-emitting unit in a non-light emitting stage after a first non-light emitting stage in the display cycle of the light-emitting unit.

21. A pixel circuit, comprising:
a light-emitting unit;
a light emitting control transistor connected with the light-emitting unit; and
a touch driving transistor connected with the light-emitting unit,
wherein in a light emitting stage, the touch driving transistor is turned off, and the light emitting control transistor is turned on to control the light-emitting unit to emit light; in a non-light emitting stage, the light emitting control transistor is turned off, and the touch driving transistor is turned on and transmits a touch driving signal to the light-emitting unit.

22. The pixel circuit according to claim 21, wherein the pixel circuit further comprises a touch driving signal line, a first end of the touch driving transistor is connected with the touch driving signal line, a second end of the touch driving transistor is connected with the light-emitting unit, and the touch driving signal line is configured to transmit the touch driving signal to the light-emitting unit through the touch driving transistor.

23. The pixel circuit according to claim 22, wherein the touch driving signal line is further configured to transmit a reset signal to the light-emitting unit through the touch driving transistor; and
in the non-light emitting stage, the touch driving transistor is turned on and transmits the touch driving signal or the reset signal to the light-emitting unit.

24. The pixel circuit according to claim 21, wherein the pixel circuit further comprises a light emitting control signal line connected with a control end of the light emitting control transistor and a control end of the touch driving transistor, and the light emitting control signal line is configured to transmit a light emitting control signal to the light emitting control transistor and the touch driving transistor;
one of the light emitting control transistor and the touch driving transistor is an N-type transistor and the other one is a P-type transistor;
wherein the pixel circuit further comprises a power supply voltage signal line and a driving transistor, and the light emitting control transistor comprises a first control transistor and a second control transistor,
wherein the light emitting control signal line is connected with control ends of the first control transistor and the second control transistor, a first end of the second control transistor is connected with the power supply voltage signal line, a second end of the second control transistor is connected with a first end of the driving transistor, a first end of the first control transistor is connected with a second end of the driving transistor, and a second end of the first control transistor is connected with the light-emitting unit;
in the light emitting stage, the light emitting control signal controls the first control transistor and the second control transistor to be turned on, and the driving transistor provides a driving current signal to the light-emitting unit through the first control transistor to cause the light-emitting unit to emit light.
